(19) United States
(12) Patent Application Publication
(10) Pub. No.: US 2025/0205760 A1
(43) Pub. Date: Jun. 26, 2025

(54) SUBSTRATE PROCESSING APPARATUS AND SUBSTRATE PROCESSING METHOD

(71) Applicant: SEMES CO., LTD., Cheonan-si (KR)

(72) Inventors: So Young PARK, Cheonan-si (KR); Bok Kyu LEE, Cheonan-si (KR)

(73) Assignee: SEMES CO., LTD., Cheonan-si (KR)

(21) Appl. No.: 18/969,391

(22) Filed: Dec. 5, 2024

(30) Foreign Application Priority Data
Dec. 26, 2023 (KR) 10-2023-0191140

(51) Int. Cl. B08B 9/08; H01L 21/306

(52) U.S. Cl. CPC B08B 9/08; H01L 21/30604

(57) ABSTRACT

Disclosed is a method of processing a substrate, the method including: a substrate processing operation of processing a substrate by supplying a treatment liquid to a substrate loaded into a processing space of a processing container; and a container cleaning operation of cleaning an interior of the processing container in a state where the substrate is unloaded from the processing space, in which the container cleaning operation includes: a periodic cleaning operation of periodically cleaning the interior of the processing container; and an emergency cleaning operation of temporarily cleaning the interior of the processing container when a set condition is satisfied.

### CROSS-REFERENCE TO RELATED APPLICATIONS

This application claims priority to and the benefit of Korean Patent Application No. 10-2023-0191140 filed in the Korean Intellectual Property Office on Dec. 26, 2023, the entire contents of which are incorporated herein by reference.

### TECHNICAL FIELD

The present invention relates to a substrate processing apparatus and a substrate processing method that treat a substrate.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

Among the processes described above, there is a wet etching process, which processes a substrate by discharging a treatment liquid onto the substrate.

In this case, the treatment liquid that processes the substrate is selectively utilizing a strong acid or a strong base depending on the wiring material of the substrate.

On the other hand, the treatment liquid may generate toxic acidic gas when processing the substrate. For example, a treatment liquid, such as hydrochloric acid, may generate acidic gases, such as hydrochloric acid gas when processing the substrate.

Because hydrochloric acid gas is very dangerous when inhaled by workers, by default, chambers for processing the substrates are exhausted internally to prevent toxic gas from being discharged to the outside.

However, the problem with this is that when the operator leaves the chamber open for a process failure or periodic inspection, the acidic gas leaks to the outside space where the operator is located and cause a personal injury.

### SUMMARY OF THE INVENTION

The present invention has been made in an effort to provide a substrate processing apparatus and a substrate processing method that prevent acidic gas inside a chamber from being discharged to the outside of the chamber when the chamber for processing a substrate is switched to an open state.

The problem to be solved by the present invention is not limited to the above-mentioned problems, and the problems not mentioned will be clearly understood by those skilled in the art from the descriptions below.

An exemplary embodiment of the present invention provides a method of processing a substrate, the method including: a substrate processing operation of processing a substrate by supplying a treatment liquid to a substrate loaded into a processing space of a processing container; and a container cleaning operation of cleaning an interior of the processing container in a state where the substrate is unloaded from the processing space, in which the container cleaning operation includes: a periodic cleaning operation of periodically cleaning the interior of the processing container; and an emergency cleaning operation of temporarily cleaning the interior of the processing container when a set condition is satisfied.

According to the exemplary embodiment, the substrate processing operation may be performed at a pressure at which a pressure in the processing space is lower than a pressure outside the processing space, and the set condition may include a case where it is detected that the pressure in the processing space is higher than the pressure outside the processing space in the substrate processing operation.

According to the exemplary embodiment, the set condition may include a case where the treatment liquid in the substrate processing operation is an acidic chemical.

According to the exemplary embodiment, the acidic chemical includes hydrochloric acid.

According to the exemplary embodiment, the emergency cleaning operation may be performed after continuous processing of the substrates with the chemical has been completed.

According to the exemplary embodiment, the method may further include a maintenance operation of maintaining a chamber in which the processing container is provided after the substrate processing operation, in which in the substrate processing operation, a chemical generating acidic gas is used as the treatment liquid, and the emergency cleaning operation may be performed after the substrate processing operation and before the maintenance operation.

According to the exemplary embodiment, the emergency cleaning operation may include supplying a cleaning liquid to a support unit rotating in the processing space to clean an upper surface of the support unit and an inner surface of the processing container.

According to the exemplary embodiment, in the emergency cleaning operation, the processing container may be moved in an up and down direction, and the processing space may be exhausted.

According to the exemplary embodiment, when a difference between a pressure in the processing space and a pressure outside the chamber is outside a set range in the substrate processing operation, the substrate processing being proceeding has been completed and the emergency cleaning operation may be performed.

According to the exemplary embodiment, the periodic cleaning operation may be performed at a set interval.

According to the exemplary embodiment, the set interval may be an interval according to the number of sheets of the substrates processed, or an interval based on time.

Another exemplary embodiment of the present invention provides an apparatus for processing a substrate, the apparatus including: a housing having an interior space; a processing container disposed in the interior space and having a processing space with an open top; a support unit for supporting a substrate within the processing space; and a liquid supply unit having a treatment liquid nozzle for supplying a treatment liquid and a cleaning liquid nozzle for supplying a cleaning liquid; an airflow supply unit providing a descending airflow into the interior space; an exhaust unit for exhausting the processing space; and a controller for controlling the liquid supply unit, the airflow supply unit, and the exhaust unit, in which the controller performs: a substrate processing operation of processing the substrate supported on the support unit with the treatment liquid; and an emergency cleaning operation of cleaning an inner wall of the processing container with the cleaning liquid when a set condition is satisfied, and the emergency cleaning operation may be performed in a state where the substrate is unloaded from the interior space.

According to the exemplary embodiment, the apparatus may further include pressure sensor for detecting a difference between a pressure in the interior space and a pressure value outside the housing, in which the controller controls the airflow supply unit and the exhaust unit such that, in the substrate processing operation, processing of the substrate is performed in a state where the pressure in the interior space is lower than the pressure outside the housing, and the controller may control the liquid supply unit such that, when the pressure sensor detects that the pressure in the interior space is higher than the pressure outside the housing in the substrate processing operation, the emergency cleaning operation is performed after the substrate is unloaded from the interior space.

According to the exemplary embodiment, the treatment liquid nozzle may supply an acidic chemical as the treatment liquid, and the controller may control the liquid supply unit such that the emergency cleaning operation is performed after a series of substrates is continuously processed with the acidic chemical.

According to the exemplary embodiment, the controller may control the liquid supply unit such that a periodic cleaning operation is performed to clean the inner wall of the processing container at regular intervals, and the periodic cleaning operation may be performed in a state where the substrate is unloaded from the interior space.

According to the exemplary embodiment, the controller may further perform a maintenance operation of maintaining a chamber in which the processing container is provided after the substrate processing operation, in which the substrate processing operation may use a chemical generating acidic gas as the treatment liquid, and the emergency cleaning operation may be performed after the substrate processing operation and before the maintenance operation.

According to the exemplary embodiment, the emergency cleaning operation may include supplying a cleaning liquid to a support unit rotating in the processing space to clean an upper surface of the support unit and an inner surface of the processing container.

According to the exemplary embodiment, when a difference between a pressure in the processing space and a pressure outside the chamber is outside a set range in the substrate processing operation, the substrate processing being proceeding has been completed and the emergency cleaning operation may be performed.

According to the exemplary embodiment, the periodic cleaning operation may be performed at a set interval.

Still another exemplary embodiment of the present invention provides a method of processing a substrate, the method including: a substrate processing operation of processing a substrate by supplying a treatment liquid to a substrate loaded into a processing space of a processing container; and a cleaning operation of cleaning an interior of the processing container in a state where the substrate is unloaded from the processing space, in which the cleaning operation may include: a periodic cleaning operation of periodically cleaning the interior of the processing container; a maintenance operation of maintaining a chamber in which the processing container is provided after the substrate processing operation; an emergency cleaning operation performed before the maintenance operation and after continuous processing for the substrates have been completed with the chemical, and including temporarily cleaning an interior of the processing container when it is detected that a pressure in the processing space is higher than a pressure outside the processing space in the substrate processing operation or when the treatment liquid is an acidic chemical, and supplying a cleaning liquid to a support unit rotating in the processing space to clean an upper surface of the support unit and an inner surface of the processing container, and the substrate processing operation is performed at a pressure at which the pressure in the processing space is lower than the pressure outside the processing space.

The present invention has the effect of preventing personal injury to operators by preventing acidic gas inside the chamber from being discharged to the outside of the chamber in advance when the chamber processing the substrate is switched to an open state.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view illustrating a substrate processing facility according to an exemplary embodiment of the present invention.

FIG. 2 is a cross-sectional view illustrating a substrate processing apparatus of FIG. 1.

FIG. 3 is a block diagram illustrating a detailed configuration of a controller of FIG. 2 in detail.

FIG. 4 is a flowchart of a substrate processing method according to an exemplary embodiment of the present invention.

FIGS. 5 and 6 are illustrative process diagrams for each of the operations illustrated in FIG. 4.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate processing, in addition to wafers.

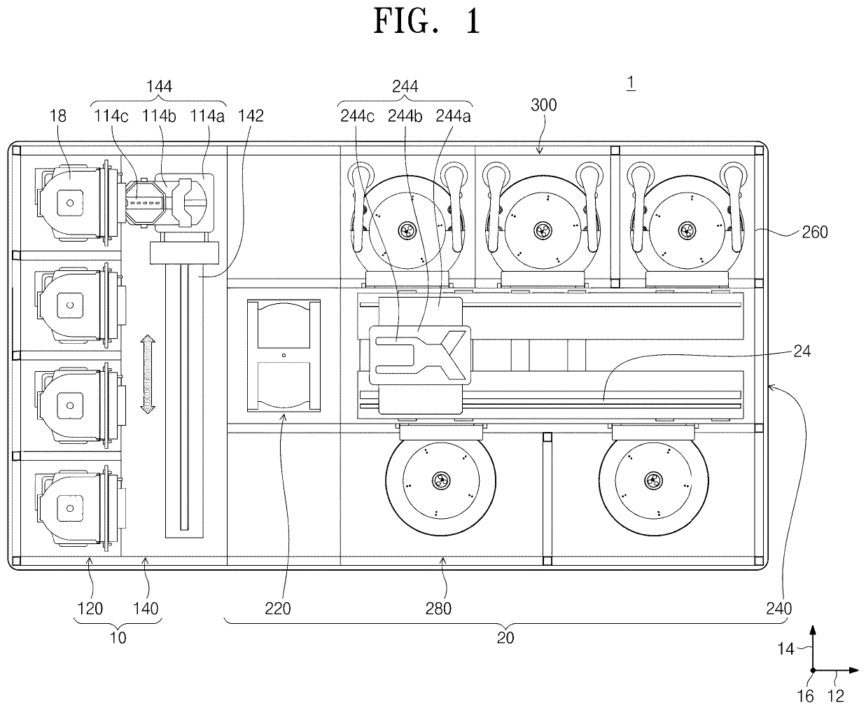

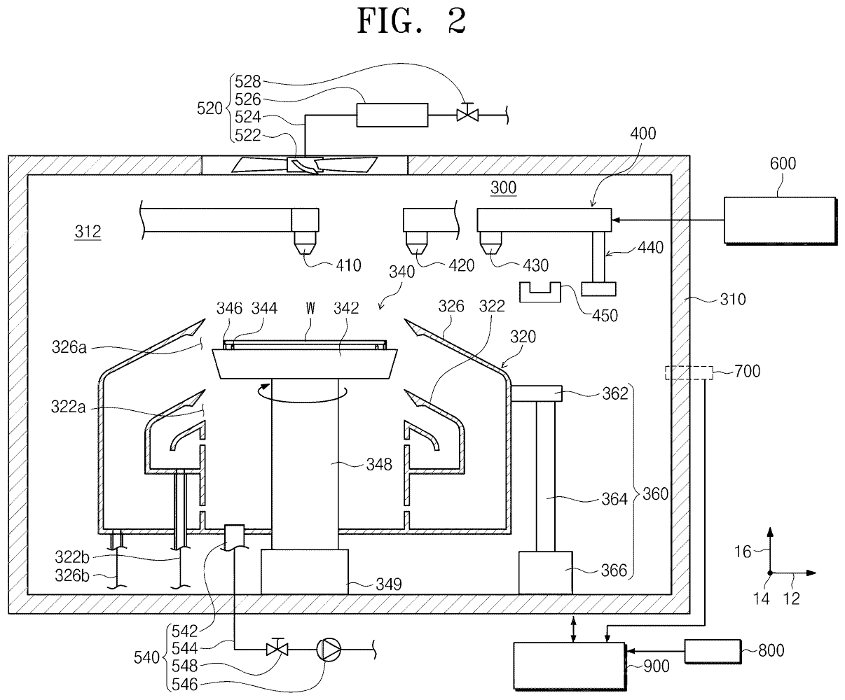

FIG. 1 is a top plan view illustrating a substrate processing facility according to an exemplary embodiment of the present invention. FIG. 2 is a cross-sectional view illustrating a substrate processing apparatus of FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided, which are arranged in a row along the second direction 14. In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. The slots are provided in a plurality in the third directions 16, and the substrates are located in a carrier to be stacked while being spaced apart from each other along the third directions 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 260 and 280 may be disposed in an array of A×B (A and B are natural numbers equal to or greater than 1) on opposite sides of the transfer chamber 240. Here, A is the number of process chambers 260,280 provided in a line along the first direction 12, and B is the number of process chambers 260,280 provided in a line along the third direction 16. When four or six process chambers 260 and 280 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing facility for cleaning the substrate, which will be described below, and the drying chamber may be a substrate processing facility for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) in which the substrate W is placed therein, and the slots (not illustrated) are provided in plural to be spaced apart from each other along the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing apparatus 300 provided in the process chamber 260 will be described. In the present exemplary embodiment, the case where a substrate processing apparatus 300 performs a liquid processing process on the substrate will be described as an example. The liquid processing process further includes a process of cleaning a substrate.

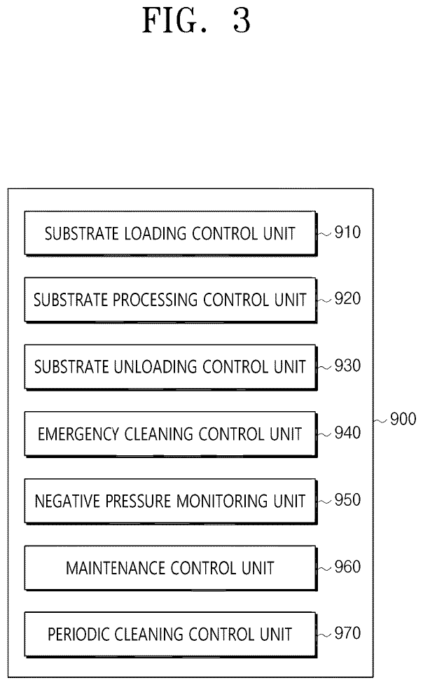

FIG. 2 is a cross-sectional view illustrating a substrate processing apparatus of FIG. 1. FIG. 3 is a block diagram illustrating a detailed configuration of a controller of FIG. 2 in detail.

Referring to FIG. 2, the substrate processing apparatus 300 further includes a chamber 310, a processing container 320, a support unit 340, a lifting unit 360, a liquid discharge unit 400, an airflow formation unit 500, a liquid supply unit 600, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal recovery container 322 and an external recovery container 326. Each of the recovery containers 322 and 326 recovers a different treatment liquid from the treatment liquids used in the process. The internal recovery container 322 is provided in the shape of an annular ring surrounding the support unit 340, and the external recovery container 326 is provided in the shape of an annular ring surrounding the inner recovery container 322. An inner space 322a of the internal recovery container 322 and a space 326a between the external recovery container 326 and the internal recovery container 322 function as inlets for the treatment liquid to flow into the internal recovery container 322 and the external recovery container 326, respectively. Recovery lines 322b and 326b are connected to the bottom surfaces of the recovery containers 322 and 326, respectively, to extend vertically in the down direction. Each of the recovery lines 322b and 326b functions as a discharge pipe to discharge the treatment liquid that has been introduced through the respective recovery containers 322 and 326. The discharged treatment liquid may be reused through an external treatment liquid regeneration system (not illustrated).

The support unit 340 is provided as a substrate support unit 340 for supporting and rotating the substrate W. The support unit 340 is disposed within the processing container 320. The substrate support unit 340 supports the substrate W and rotates the substrate W during the process progress. The support unit 340 includes a spin chuck 342, a support pin 344, a chuck pin 346, and a rotation shaft 348. The spin chuck 342 has a top surface that is substantially circular when viewed from the top. The rotation shaft 348 that is rotatable by a driver is fixedly coupled to the bottom surface of the spin chuck 342. In one example, the driver may be formed of a motor 349. A plurality of support pins 344 is provided. The support pins 344 are spaced apart on the edge portion of a top surface of the spin chuck 342 and protrude upwardly from the spin chuck 342. The support pins 334 are arranged in combination with each other to have an overall annular ring shape. The support pin 344 supports an edge of the rear surface of the substrate W so that the substrate W is spaced apart from the top surface of the spin chuck 2631 at a predetermined distance. A plurality of chuck pins 346 is provided. The chuck pins 346 are disposed to be further away from a center of the spin chuck 342 than the support pins 344. The chuck pin 346 is provided to protrude upwardly from the spin chuck 342. The chuck pin 346 supports a lateral portion of the substrate W to prevent the substrate W from laterally deviating from its stationary position when the support unit 340 is rotated. The chuck pin 346 is provided to be linearly movable between a standby position and a support position along a radial direction of the spin chuck 342. The standby position is a position further away from the center of the spin chuck 342 relative to the support position. When the substrate W is loaded into or unloaded from the support unit 340, the chuck pin 346 is positioned in the standby position, and when a process is being performed on the substrate W, the chuck pin 346 is positioned in the support position. In the support position, the chuck pin 346 is in contact with the lateral portion of the substrate W.

The lifting unit 360 regulates the relative height between the processing container 320 and the support unit 340. The lifting unit 360 linearly moves the processing container 320 in the up and down direction. As the processing container 320 is moved up and down, the relative height of the processing container 320 with respect to the support unit 340 changes. The lifting unit 460 includes a bracket 362, a moving shaft 364, and a driver 366. The bracket 362 is fixedly installed on the outer wall of the processing container 320, and the moving shaft 364, which is moved in the vertical direction by the driver 366, is fixedly coupled to the bracket 362. When the substrate W is placed on the support unit 340 or lifted from the support unit 340, the processing container 320 is lowered so that the support unit 340 protrudes above the processing container 320. Furthermore, when the process is in progress, the height of the processing container 320 is regulated so that the treatment liquid may flow into the preset recovery containers 322 and 326 according to the type of treatment liquid that has been supplied to the substrate W.

Unlike the above description, the lifting unit 360 may move the support unit 340 in the upper and lower directions instead of the processing container 320.

The liquid discharge unit 400 supplies various types of liquids to the substrate W. The liquid discharge unit 400 further includes a plurality of nozzles 410 to 430. Each nozzle is moved to a process position and a standby position by a nozzle position driver 440. A process position is defined herein as a position where the nozzles 410 to 430 are capable of discharging liquid onto the substrate W positioned within the processing container 320, and a standby position is defined as a position where the nozzles 410 to 430 are waiting outside of the process position. According to an example, the process position may be a position at which the nozzles 410 to 430 may supply a liquid to the center of the substrate W. For example, when viewed from above, the nozzles 410 to 430 may be moved linearly or axially to be moved between the process position and the standby position. The treatment liquid discharged from the liquid discharge unit 400 to the substrate W may be a treatment liquid for processing the substrate W. Additionally, in the standby position, a recovery pipe 450 may be disposed below the third nozzle 430. The recovery pipe 450 recovers the treatment liquid when the third nozzle 430 discharges the treatment liquid for cleaning.

The plurality of nozzles 410 to 430 discharges different types of liquid. The treatment liquid discharged from the nozzles 410 to 430 may include at least one of a chemical, a rinse solution, a cleaning liquid, and a drying fluid. Referring to the exemplary embodiment of FIG. 2, a first nozzle 410 may be a nozzle for discharging chemicals. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. Further, the second nozzle 420 may be a nozzle for discharging a rinse solution. The rinse solution may be a solution capable of rinsing the chemicals remaining on the substrate W. For example, the rinse solution may be pure water. Further, the second nozzle 420 may be a nozzle that discharges a cleaning liquid. The cleaning liquid may be a solution that treats the support unit 340, the processing container 320, and the recovery pipe 450 after processing the substrate W. Further, the third nozzle 430 may be a nozzle for discharging a drying fluid. The drying fluid may be provided as a solution capable of substituting the residual rinse solution on the substrate W. The drying fluid may be a solution having lower surface tension than the rinse solution. The drying fluid may be an organic solvent. The drying fluid may be isopropyl alcohol (IPA). The third nozzle 430 may be connected to the liquid supply unit 600 to receive a supply of a drying fluid.

The airflow formation unit 500 forms a downward airflow in the processing space 312. The airflow formation unit 500 supplies airflow from a top portion of the chamber 310 and exhausts airflow from a lower portion of the chamber 310. The airflow formation unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312 so that the negative pressure in the processing space 312 is lower than the outside air pressure. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that an exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

The liquid supply unit 600 may supply liquid to each of the plurality of nozzles 410 to 430.

The pressure sensor 700 may be installed in the chamber 310. The pressure sensor 700 may detect a pressure value in the processing space 312. The pressure sensor 700 may transmit the detected pressure value to the controller 900. Additionally, the pressure sensor 700 may detect an outside air pressure value for the outside of the chamber 310. In this case, the pressure sensor 700 may detect a difference value between the pressure value in the processing space 312 and the outside air pressure value.

The input device 800 is interfaced with the controller 900 and may input input values to the controller 900. The input device 800 may be an input device, such as a touch panel, a push button panel for control, or a mouse. The input device unit 800 may be utilized to operate the controller 900 in a manual mode. Accordingly, the input device unit 800 may receive an input value by a manipulation of an operator.

The controller 900 controls the driving of the processing container 320, the support unit 340, the lifting unit 360, the liquid discharge unit 400, the airflow formation unit 500, and the liquid supply unit 600 with a preset process algorithm to process the substrate W.

In one example, the controller 900 may include a substrate loading control unit 910, a substrate processing control unit 920, a substrate unloading control unit 930, an emergency cleaning control unit 940, and a negative pressure monitoring unit 950, depending on the function being controlled, and may further include a maintenance control unit 960, and a periodic cleaning control unit 970. In this case, each of the substrate loading control unit 910, the substrate processing control unit 920, the substrate unloading control unit 930, the emergency cleaning control unit 940, and the negative pressure monitoring unit 950, the maintenance control unit 960, and the periodic cleaning control unit 970 may be implemented hardware or software using logic elements or computational algorithms. Each of the substrate loading control unit 910, the substrate processing control unit 920, the substrate unloading control unit 930, the emergency cleaning control unit 940, and the negative pressure monitoring unit 950, the maintenance control unit 960, and the periodic cleaning control unit 970 may be a series of processors that perform each of the operations in the substrate processing method described hereinafter.

The substrate loading control unit 910 controls the main robot 244 to load the substrate W into the processing space 312 of the chamber 310. In this case, the main robot 244 may seat the substrate W on the support unit 340.

The substrate processing control unit 920 may control the driving of the liquid discharge unit to discharge a treatment liquid onto the substrate W disposed in the processing space 312. For example, the substrate processing control unit 920 may discharge a treatment liquid from the first nozzle 410 or discharge a drying fluid from the third nozzle 430. In the meantime, the treatment liquid discharged from the first nozzle 410 may generate toxic acidic gas. For example, the first nozzle 410 may selectively discharge strong acids, such as hydrochloric acid, sulfuric acid, or hydrofluoric acid, as the treatment liquid, and in this case, the hydrochloric acid, sulfuric acid, and hydrofluoric acid may generate acid gas, such as hydrochloric acid gas, sulfuric acid gas, and hydrofluoric acid gas, respectively. In this case, the acidic gas may cause a safety accident when inhaled by an operator. In addition, the substrate processing control unit 920 may control the rotation drive of the support unit 340 to discharge the treatment liquid in a state in which the substrate W is rotated. The substrate processing control unit 920 may control the driver 440 to adjust the position of the nozzles 410 to 430 to discharge the treatment liquid.

The substrate unloading control unit 930 controls the main robot 244 to discharge the substrate W within the processing space 312 to the outside of the chamber 310. The substrate unloading control unit 930 may be driven before the emergency cleaning control unit 940 is driven to ensure that no substrate W is left within the processing space 312.

The emergency cleaning control unit 940 may cause a cleaning fluid to be discharged from the second nozzle 420 to clean the interior of the processing space 312. In this case, the emergency cleaning control unit 940 may stop the driving of the substrate processing control unit 920 to ensure that no processing fluid is supplied from the first nozzle 410. In addition, the emergency cleaning control unit 940 may control the driver 440 to cause the second nozzle 420 to discharge the cleaning fluid while moving moves through the upper space of the support unit 340 and the processing container 320. Thus, any residual treatment fluid in the support unit 340 and the processing container 320 may be removed to minimize the generation of acidic gas. In this case, the emergency cleaning control unit 940 may drive the lifting unit 360 to lift the top end of the processing container 320 to a position higher than the top end of the support unit 340. Accordingly, the exhaust unit may concentrate the exhaust flow by the lifted processing container 320 to increase the exhaust rate of the acid gas.

The negative pressure monitoring unit 950 monitors a negative pressure value in the processing space 312. In this case, the negative pressure monitoring unit 950 may control the emergency cleaning control unit 940 to proceed after the substrate processing control unit 920 stops processing the substrate when the negative pressure value in the processing space 312 is higher than a preset value. The negative pressure monitoring unit 950 may also control the emergency cleaning control part 940 to proceed after stopping the substrate processing control unit 920 when a difference value between the negative pressure value in the processing space 312 and an outside air pressure value in the chamber 310 is lower than a set value. In one example, the negative pressure monitoring unit 950 may be activated when the negative pressure in the processing space 312 is higher than the preset value due to an operator switching the chamber 310 to an open state for failure inspection or periodic inspection.

The maintenance control unit 960 stops the driving of the substrate processing control unit 920. In this case, the maintenance control unit 960 may stop the driving of the substrate processing control unit 920 when an input value is input from the input device unit 800, and then drive the emergency cleaning control unit 940. Thus, when an operator operates the input device unit 800 to stop the operation of the substrate processing equipment 1 for failure inspection or periodic inspection, acid gas emission may be minimized by allowing the interior of the processing space 312 to be cleaned.

When the number of times of the processing of the substrate W is equal to or greater than a predetermined number, or when the number of hours the substrates W have been processed exceeds a predetermined number of hours, the periodic cleaning control unit 970 discharges a cleaning liquid from the second nozzle 420 to clean the interior of the processing space 312. Since it is difficult for the periodic cleaning control unit 970 to prevent acid gas from being discharged when an operator is performing the failure inspection or periodic inspection, the emergency cleaning control unit 940 is driven when a specific event occurs to minimize the discharge of acid gas.

The following describes the substrate processing method of the substrate processing apparatus as described above.

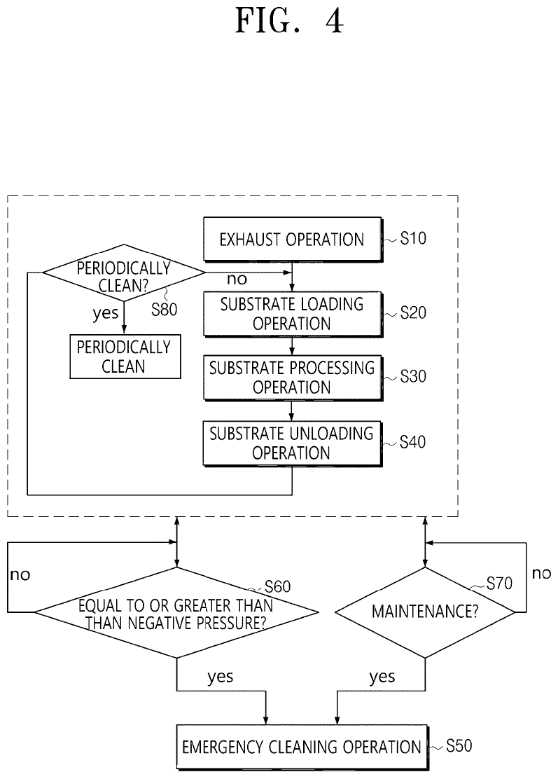

FIG. 4 is a flowchart of a substrate processing method according to an exemplary embodiment of the present invention.

As illustrated in FIG. 4, a substrate processing method according to an exemplary embodiment of the present invention includes an exhaust operation S10, a substrate loading operation S20, a substrate processing operation S30, a substrate unloading operation S40, an emergency cleaning operation S50, and a negative pressure monitoring operation S60, and may further include a maintenance operation S70, and a periodic cleaning operation S80.

In the exhaust operation S10, an exhaust unit exhausts the processing space 312 within the chamber 310. In this case, the exhaust operation S10 may exhaust the processing space 312 such that the negative pressure in the processing space 312 is lower than the outside air pressure of the chamber 310.

In the substrate loading operation S20, the substrate loading control unit 910 controls the main robot 244 to load the substrate W into the processing space 312 within the chamber 310.

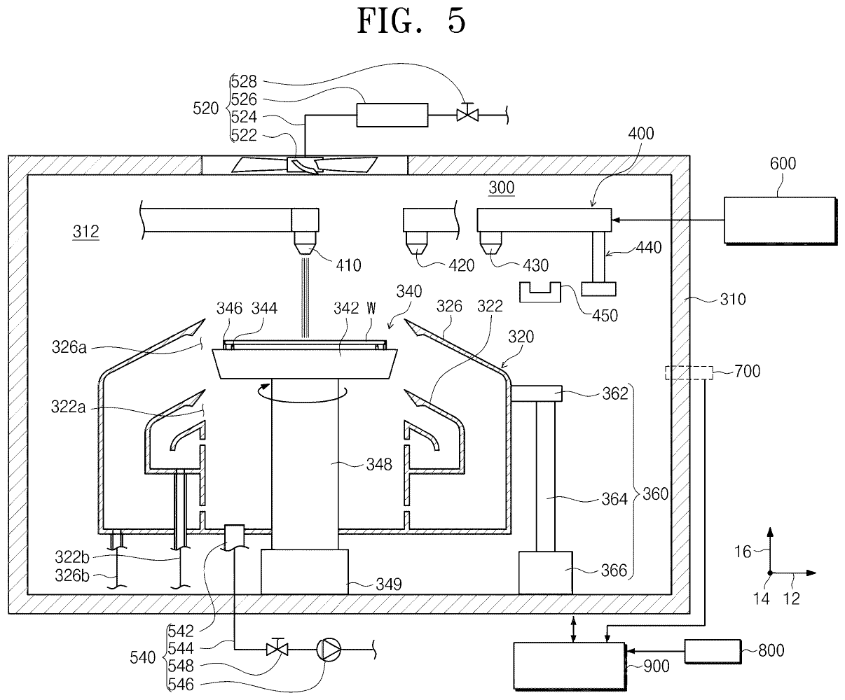

In the substrate processing operation S30, as illustrated in FIG. 5, the substrate processing control unit 920 controls the liquid discharge unit to discharge a treatment liquid onto the substrate W disposed in the processing space 312. As described above, the substrate processing control unit 920 may discharge a treatment liquid from the first nozzle 410 or a drying fluid from the third nozzle 430. In this case, the treatment liquid may generate acidic gas when it is formed from a strong acid. Furthermore, in the substrate processing operation S30, the substrate processing control unit 920 may control the rotation drive of the support unit 340 to discharge the treatment liquid in a state in which the substrate W is rotated. In the substrate processing operation S30, the substrate processing control unit 920 may control the driver to discharge the treatment liquid while adjusting the position of the nozzles.

In the substrate unloading operation S40, the substrate unloading control unit 930 controls the main robot 244 to unload the substrate W in the processing space 312 to the outside of the chamber 310.

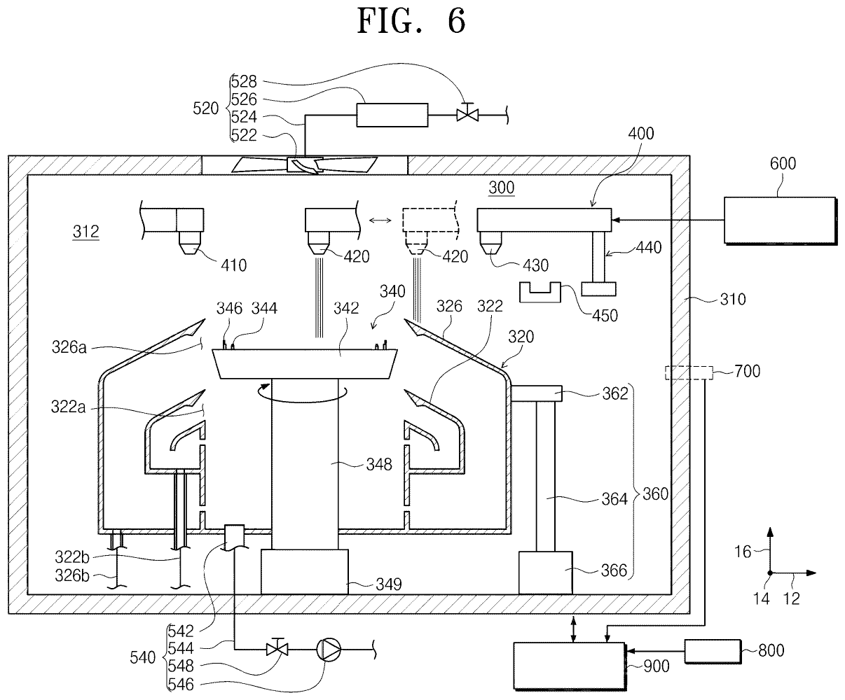

In the emergency cleaning operation S50, when a preset condition is met, the emergency cleaning control unit 940 discharges a cleaning fluid from the second nozzle 420 into the processing space 312 to clean the processing space 312, as illustrated in FIG. 6. The emergency cleaning operation S50 may be included in a container cleaning operation that cleans the processing container 320. The emergency cleaning operation S50 may be performed after the substrate has been processed by the substrate processing operation S30. Here, the preset condition may be determined by the negative pressure monitoring operation S60 or the maintenance operation S70 described later. In this emergency cleaning operation S50, the emergency cleaning control unit 940 may set the first nozzle 410 to a closed state to prevent discharge of the treatment liquid and set the second nozzle 420 to an open state to allow discharge of the cleaning liquid into the processing space 312. Further, in the emergency cleaning operation S50, the emergency cleaning control unit 940 may control the driver to cause the processing container 320 to move in an upward and downward direction, and cause the second nozzle 420 to discharge the cleaning liquid into the support unit 340 and the processing container 320 while moving the upper space of the support unit 340 and the processing container 320. The cleaning liquid that cleans the processing space 312 is recovered through the recovery lines 322b and 326b. Thus, acid gas may be minimized by cleaning the processing space only with the processing liquid that remains inside the processing space 312 with no processing liquid supplied as a cleaning liquid. Further, in the emergency cleaning operation S50, the emergency cleaning control unit 940 may control the lifting unit 360 to lift the top end of the processing container 320 to a position higher than the top end of the support unit 340 when cleaning the processing space 312 with the cleaning liquid. Thus, the exhaust unit may have an exhaust flow concentrated by the lifted processing container 320, resulting in an increased exhaust rate of acidic gas.

In the negative pressure monitoring operation S60, the negative pressure monitoring unit 950 monitors the negative pressure of the processing space 312 within the chamber 310 to proceed with the emergency cleaning operation S50 when the negative pressure of the processing space 312 becomes higher than a preset value. In this case, in the negative pressure monitoring operation S60, the negative pressure monitoring unit 950 may detect a negative pressure value of the processing space 312 installed in the chamber 310 and detect an outside air pressure value of the chamber 310, and in this case, the negative pressure monitoring unit 950 may stop the substrate processing operation S30 when the difference value between the negative pressure value of the processing space 312 and the outside air pressure value of the chamber 310 is lower than a set value, and then allow the emergency cleaning operation S50 to proceed. Thus, in a situation where the outside air pressure of the outside of the chamber 310 becomes so lower than the negative pressure in the processing space 312 that the acidic gas in the processing space 312 is discharged to the outside of the chamber 310, the processing space 312 may be cleaned to prevent the remaining toxic gas from being discharged to the outside of the chamber 310.

In the maintenance operation S70, the maintenance control unit 960 stops the running of the substrate processing operation S30. In this case, the negative pressure monitoring operation S60 may occur prior to proceeding with the emergency cleaning operation S50 when the negative pressure in the processing space 312 becomes higher than the preset value, as described above. Here, the maintenance operation S70 may proceed by an input value input by the input device unit 800 as described above.

The periodic cleaning operation S80 is performed by the periodic cleaning control unit 970, and when the number of times of the processing of the substrates W is equal to or greater than a predetermined number, or when the number of hours the substrate W has been processed exceeds a predetermined number of hours, the cleaning liquid is discharged from the second nozzle 420 to clean the interior of the processing space 312. The periodic cleaning operation S80 may be included in a container cleaning operation that cleans the processing container 320.

In this way, the substrate processing apparatus and the substrate processing method according to the exemplary embodiments of the present invention minimizes the discharge of acidic gas inside the chamber 310 to the outside by automatically cleaning the processing space 312 of the chamber 310 when an operator wishes to perform a failure inspection or periodic inspection of the substrate processing apparatus so that the chamber 310 is switched to an open state or the substrate processing apparatus is stopped running.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

1. A method of processing a substrate, the method comprising:
a substrate processing operation of processing a substrate by supplying a treatment liquid to a substrate loaded into a processing space of a processing container; and
a container cleaning operation of cleaning an interior of the processing container in a state where the substrate is unloaded from the processing space,
wherein the container cleaning operation includes:
a periodic cleaning operation of periodically cleaning the interior of the processing container; and
an emergency cleaning operation of temporarily cleaning the interior of the processing container when a set condition is satisfied.

2. The method of claim 1, wherein the substrate processing operation is performed at a pressure at which a pressure in the processing space is lower than a pressure outside the processing space, and
the set condition includes a case where it is detected that the pressure in the processing space is higher than the pressure outside the processing space in the substrate processing operation.

3. The method of claim 1, wherein the set condition includes a case where the treatment liquid in the substrate processing operation is an acidic chemical.

4. The method of claim 3, wherein the acidic chemical includes hydrochloric acid.

5. The method of claim 1, wherein the emergency cleaning operation is performed after continuous processing of the substrates with the chemical has been completed.

6. The method of claim 1, further comprising:
a maintenance operation of maintaining a chamber in which the processing container is provided after the substrate processing operation,
wherein in the substrate processing operation, a chemical generating acidic gas is used as the treatment liquid, and
the emergency cleaning operation is performed after the substrate processing operation and before the maintenance operation.

7. The method of claim 1, wherein the emergency cleaning operation includes supplying a cleaning liquid to a support unit rotating in the processing space to clean an upper surface of the support unit and an inner surface of the processing container.

8. The method of claim 7, wherein in the emergency cleaning operation, the processing container is moved in an up and down direction, and the processing space is exhausted.

9. The method of claim 1, wherein when a difference between a pressure in the processing space and a pressure outside the chamber is outside a set range in the substrate processing operation, the substrate processing being proceeding has been completed and the emergency cleaning operation is performed.

10. The method of claim 1, wherein the periodic cleaning operation is performed at a set interval.

11. The method of claim 10, wherein the set interval is an interval according to the number of sheets of the substrates processed, or an interval based on time.

12.-19. (canceled)

20. A method of processing a substrate, the method comprising:
a substrate processing operation of processing a substrate by supplying a treatment liquid to a substrate loaded into a processing space of a processing container; and
a cleaning operation of cleaning an interior of the processing container in a state where the substrate is unloaded from the processing space,
wherein the cleaning operation includes:
a periodic cleaning operation of periodically cleaning the interior of the processing container;
a maintenance operation of maintaining a chamber in which the processing container is provided after the substrate processing operation;
an emergency cleaning operation performed before the maintenance operation and after continuous processing for the substrates have been completed with the chemical, and including temporarily cleaning an interior of the processing container when it is detected that a pressure in the processing space is higher than a pressure outside the processing space in the substrate processing operation or when the treatment liquid is an acidic chemical, and supplying a cleaning liquid to a support unit rotating in the processing space to clean an upper surface of the support unit and an inner surface of the processing container, and
the substrate processing operation is performed at a pressure at which the pressure in the processing space is lower than the pressure outside the processing space.
